(19) United States
(12) Patent Application Publication
(10) Pub. No.: US 2024/0026532 A1
(43) Pub. Date: Jan. 25, 2024

(54) SUBSTRATE PROCESSING METHOD

(71) Applicant: ASM IP Holding B.V., Almere (NL)

(72) Inventors: YeaHyun Gu, Hwaseong-si (KR); KwangMan Ko, Uiwang-si (KR); HyunChul Kim, Hwaseong-si (KR); HakJoo Lee, Hwaseong-si (KR); Takahiro Arai, Sagamihara-shi (JP); Hiroshi Kou, Tokyo (JP)

(21) Appl. No.: 18/222,012

(22) Filed: Jul. 14, 2023

Related U.S. Application Data
(60) Provisional application No. 63/390,395, filed on Jul. 19, 2022.

(51) Int. Cl. C23C 16/455; C23C 16/56; C23C 16/40

(52) U.S. Cl. CPC C23C 16/45529; C23C 16/45553; C23C 16/56; C23C 16/402; C23C 16/405

(57) ABSTRACT

Provided is a method for forming a TiO₂—SiO₂ laminated layer for suppressing a crystallization of TiO₂ layer. In one embodiment, a TiO₂—SiO₂ laminated layer may be formed by alternately forming and stacking a TiO₂ layer and a SiO₂ layer by plasma atomic layer deposition. A TiO₂—SiO₂ laminated layer has a high film strength compared to the conventional SiO₂ layer and a crystallization of TiO₂ layer is suppressed by forming a laminated layer and controlling a cycle ratio of the step of forming a TiO₂ layer to the step of forming a SiO₂ layer.

### CROSS-REFERENCE TO RELATED APPLICATIONS

This application claims priority to U.S. Provisional Patent Application Ser. No. 63/390,395 filed Jul. 19, 2022 titled SUBSTRATE PROCESSING METHOD, the disclosure of which is hereby incorporated by reference in its entirety.

### BACKGROUND

### 1. Technical Field

The disclosure relates to a substrate processing method, especially to a method for suppressing a crystallization of a layer formed on a substrate.

### 2. Description of the Related Arts

As the degree of integration of a semiconductor device increases and the line width of the semiconductor circuit becomes narrow, a thickness of a layer formed on structures of the semiconductor devices becomes thinner. A SiO₂ layer is widely used in a film forming process. But as the line width of the device circuit narrows, the thickness of SiO₂ layer is becoming thinner. Therefore, a thin SiO₂ layer has a limited application to a metal interconnection process or to a spacer layer and a hard mask layer in patterning process. This is because it may result in low insulating properties in interconnection process, lean, collapse, or over-etching of spacer layer due to poor mechanical strength and underlayer damage in hard mask process.

FIG. 1 (A) to 1(D) illustrate a patterning process for forming a SiO₂ spacer and defects occurring during the process.

In FIG. 1(A), a hard mask oxide layer 3 may be formed on a polysilicon layer 4, and a SiO₂ spacer layer 1 may be formed on a patterned carbon layer 2 which may be formed on the hard mask layer 3. After that, the upper part of the SiO₂ spacer layer 1 and the carbon layer 2 may be removed (FIG. 1(B) and FIG. 1(C)). But due to thin thickness, the film strength of SiO₂ layer may become weak, lean, or be overly etched (FIG. 1(C)).

This may cause defects such as non-uniform spacing and width between patterns in the subsequent patterning process for patterning the polysilicon layer 4 as shown in FIG. 1(D).

Therefore, a TiO₂ layer is considered as an alternative to SiO₂ layer as TiO₂ layer has better insulating characteristics (e.g. high dielectric constant) and mechanical strength than SiO₂ layer. But the TiO₂ layer may be partially crystallized on the surface when the TiO₂ layer is thicker than 50 nm and the whole layer may be crystallized in the subsequent annealing process. Therefore, the insulating characteristics of the TiO₂ layer may decline.

The characteristics of TiO₂ layer may vary depending on the phase, the shape, and the sizes of the crystal of the TiO₂ layer. Therefore, those parameters may affect the subsequent processes. For instance, a crystal bump formed on the TiO₂ spacer layer in patterning process may lead to a defect in the subsequent etching process and cause a device failure afterwards.

FIG. 2(A) to 2(D) are SEM (Scanning Electron Microscopy) images of crystal bumps formed on the TiO₂ layer depending on the thickness of TiO₂ layer in the conventional TiO₂ layer forming process.

FIG. 2(A) to 2(D) show various thickness of TiO₂ layer, for instance, 37 nm (FIG. 2(A)), 55 nm (FIG. 2(B)), 74 nm (FIG. 2(C)), and 92 nm (FIG. 2(D)). As shown in FIG. 2, the crystal bumps 5, 6 may be formed on TiO₂ layer thicker than 50 nm.

FIG. 3 (A) to 3(D) are TEM (Transmission Electron Micrography) images showing that a bump(C) formed on the non-crystalline TiO₂ layer which is deposited on the Si substrate is crystalline in which TiO₂ layer may be 150 nm.

In FIG. 3(A) to FIG. 3(D), a TiO₂ layer includes a non-crystalline portion A and a crystalline portion(bump) C. The non-crystalline portion and the crystalline portion may have different wet etch rate characteristics and cause a defective patterning in the subsequent etching process.

A TiO₂ layer may be used for a dielectric layer of CIS(CMOS Image Sensor) optical device, but the crystalized TiO₂ layer may cause a light scattering and the optical characteristics of the CIS device may deteriorate.

### SUMMARY

In one or more embodiments, a method for suppressing a crystallization of TiO₂ layer may be provided. In more detail, a laminated layer containing TiO₂ layer may be formed by plasma enhanced atomic layer deposition method.

In one or more embodiments, the laminated layer may be formed by forming a first layer comprising a TiO₂ layer and forming a second layer comprising a SiO₂ layer on the first layer by plasma atomic layer deposition method.

In one or more embodiments, the first layer may be formed by supplying a first source gas and a first reactant alternately and sequentially and the cycle may be repeated a plurality of times. The second layer may be formed by supplying a second source gas and a second reactant alternately and sequentially and the cycle may be repeated a plurality of times.

In one or more embodiments, a cycle ratio of the step for forming the first layer to the step for forming the second layer may be below 20:1, more preferably below 10:1

In one or more embodiments, a post treatment may be carried out to the laminated layer comprising the first layer and the second layer.

In one or more embodiments, the laminated layer may be comprised of at least one of TiO₂—SiO₂ layer, TiO₂—TiN layer, TiO₂—SiN and TiO₂—TaN and the mixture thereof.

In one or more embodiments, the annealing temperature may be below 850° C., more preferably below 400° C.

In one or more embodiments, the laminated layer comprising the first layer and the second layer may be non-crystalline.

In one or more embodiments, the laminated layer comprising the first layer and the second layer may be at least one of spacer layer, hard mask layer and gap-filling layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1(A) to FIG. 1(D) illustrate a SiO₂ spacer layer formed for patterning process and patterning failures.

FIG. 2(A) to FIG. 2(D) are SEM images of bumps formed on TiO₂ layer according to the thickness of TiO₂ layer.

FIG. 3(A) to FIG. 3(D) are TEM images of non-crystalline portion of TiO₂ layer and crystalline portion of TiO₂ layer.

FIG. 4 is a view of substrate processing method according to the disclosure.

FIG. 5 is a view of timing graph of substrate processing method according to the disclosure.

FIG. 6 is a XRD date showing a crystallinity of TiO₂—SiO₂ layer in accordance with the cycle ratio of TiO₂ layer to SiO₂ layer.

FIG. 7 illustrates a conceptual view of TiO₂—TiN laminated layer

FIG. 8 is a XRD data showing a crystallinity of TiO₂ layer in accordance with the annealing temperature.

FIG. 9 is a XRD data showing a crystallinity of TiO₂—TiN laminated layer in accordance with the cycle ratio of forming a TiO₂ layer to forming a TiN layer and annealing temperature.

FIG. 10(A) to FIG. 10(D) illustrate an application of TiO₂—SiO₂ laminated layer as a spacer layer formed on a substrate in patterning process

FIG. 11(A) to FIG. 11(C) illustrate another application of TiO₂—SiO₂ laminated layer as a hard mask layer formed on the substrate in patterning process.

FIG. 12 illustrates another application of TiO₂—SiO₂ laminated layer for barrier layer in interconnection process.

### DETAILED DESCRIPTION OF THE DISCLOSURE

The disclosure relates to a method for resolving the aforementioned problem. More specifically, the disclosure relates to a method for suppressing a crystallization of and maintaining a non-crystalline structure when carrying out an annealing process after forming a TiO₂ layer on the substrate.

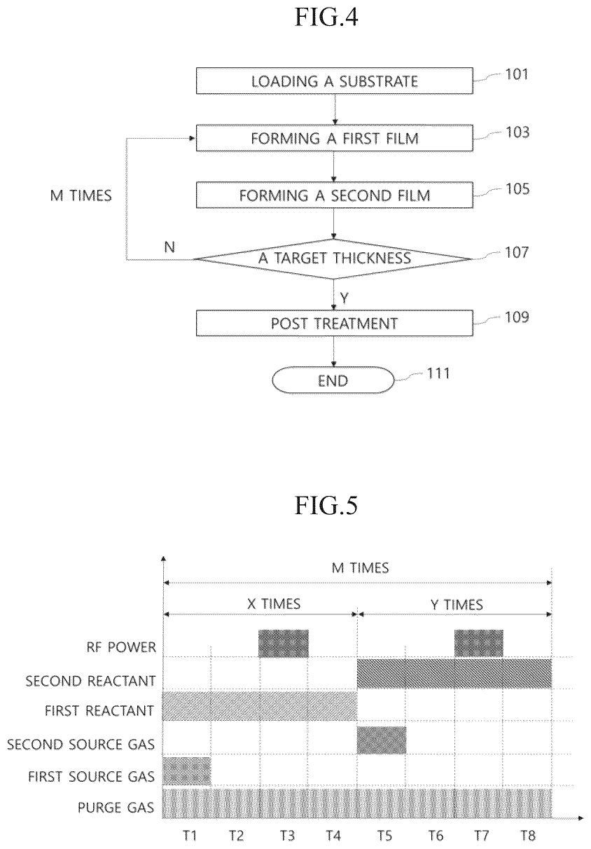

FIG. 4 is a view of substrate processing method of an embodiment of the disclosure. Detailed description of FIG. 4 is set forth as follows.

First step 101: a substrate may be loaded onto a susceptor of a reactor. The substrate may be one of Si, GaAs, Sapphire or equivalents thereof. The substrate may include a 3D structure on it. For instance, this may include a gap structure, STI(Shallow Trench Isolation), a stacked gate structure of 3D VNAND, a gate structure of memory device, or a patterned structure for pattering process.

The susceptor on which a substrate may be loaded may be mounted on a heating block. The substrate may be placed opposite to a gas supply unit, which may be a showerhead, for instance. At least one of the gas supply unit and the heating block may be connected to a RF power generator and a matching network. In case the gas supply unit is connected to the RF power generator, the gas supply unit may act as an electrode supplying RF power to the reactor to generate a plasma in a reaction space between the gas supply unit and the heating block. In another embodiment, the plasma may be generated remotely and be supplied to the reactor.

Second step 103: a first layer may be formed on the structure of the substrate. In an embodiment, the first layer may be formed by atomic layer deposition method. For instance, a first source gas and a first reactant may be sequentially and alternately supplied to the substrate. This may form a conformal first layer on the structure formed on the substrate.

The first source gas may contain a metallic element. For instance, the first source gas may contain titanium (Ti). The first source gas may comprise Tetrikis-Dimethylamino Titanium(TDMAT), Ti[N(CH₃)₂]₄; Tetra-ethylmethylamino Titanium(TEMATi), [(CH₃C₂H₅)N]₄Ti); Titanium alkoxide(e.g. Titanium tetraisopropoxide (TTIP), Ti(OC₃H₇)₄; Titanium tetrabutoxide, Ti[OC(CH₃)₃]₄); Titanium tetrachloride, TiCl₄; or mixtures thereof.

The first reactant may contain an oxygen. For instance, the first reactant may be at least one of O₂, CO₂, O₃, N₂O and NO₂ or the mixture thereof. In another embodiment, the first reactant may be activated by RF power and generate an oxygen plasma. The activated first reactant may react with the first source gas adsorbed on the substrate and form an oxide layer. The second step 103 may be repeated a plurality of times (X times).

In another embodiment, the first layer may be formed by pulsed plasma chemical vapor deposition method in which a first source gas may be supplied continuously and an activated first reactant (e.g. oxygen plasma) may be supplied intermittently. In the alternative, a first source gas may be supplied intermittently and an activated first reactant (e.g. oxygen plasma) may be supplied continuously. In an embodiment of the disclosure, the first layer may comprise TiO₂.

Third step 105: a second layer may be formed on the first layer. In an embodiment, the second layer may be formed by atomic layer deposition method. For instance, a second source gas and a second reactant may be sequentially and alternately supplied to the substrate and form a conformal second layer on the first layer formed on the substrate.

The second source gas may contain a semi-metallic element or a metallic element. For instance, the second source gas may contain at least one of a silicon (Si), a titanium (Ti) and tantalum (Ta). The second source gas may comprise TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; __Tetrikis-Dimethylamino Titanium(TDMAT), Ti[N(CH₃)₂]₄; Tetra-ethylmethylamino Titanium(TEMATi), [(CH₃C₂H₅)N]₄Ti); Titanium alkoxide(e.g. Titanium tetraisopropoxide (TTIP), Ti(OC₃H₇)₄; Titanium tetrabutoxide, Ti[OC(CH₃)₃]₄),; Titanium tetrachloride, TiCl₄; Tertiary-Butyl Imido Tris-Diethyl Tantalum (TBTDET), [(^{t}BuN)Ta(N(C₂H₅)₂)₃]; Tertiary-Butyl Imido Tris-Ethylmethylamino Tantalum (TBITEMATa), [(^{t}BuN)Ta(N(CH₃)(C₂H₅))₃] or mixtures thereof.

The second reactant may contain an oxygen or nitrogen. For instance, the second reactant may be at least one of O₂, CO₂, O₃, N₂O, NO₂, or mixtures thereof. For instance, the second reactant may be at least one of O₂, CO₂, O₃, N₂O, NO₂, N₂, NH₃, N₂H₂,N₂H₄, or mixtures thereof. In another embodiment, the second reactant may be activated by RF power and generate at least one of oxygen plasma or nitrogen plasma.

The activated second reactant may react with the second source gas adsorbed on the substrate and form an oxide layer or a nitride layer. The third step 105 may be repeated a plurality of times (Y times).

In another embodiment, the second layer may be formed by pulsed plasma chemical vapor deposition method in which a second source gas may be supplied continuously and an activated second reactant (e.g. oxygen plasma) may be supplied intermittently. In the alternative, a second source gas may be supplied intermittently and an activated second reactant (e.g. oxygen plasma, nitrogen plasma) may be supplied continuously. In an embodiment of the disclosure, the second layer may comprise at least one of SiO₂, SiN, TiN, or TaN.

In an embodiment, the cycle ratio of the second step 103 for forming the first layer to the third step 105 for forming the second layer, that is X:Y, may be set below the maximum ratio for suppressing the crystallization of the first layer. For instance, the cycle ratio of the second step 103 for forming the first layer to the third step 105 for forming the second layer (X:Y) may be below 10:1 (≤10:1). That may mean 10 cycles for forming the first layer and a cycle for forming the second layer may be repeated a plurality of times. In another embodiment, the cycle ratio of the second step 103 and the third step 105 may be 5:1, 3:1, or 1:1.

Fourth step 107: whether the total thickness of the first layers and the second layers formed through the second step 103 and the third step 105 respectively reaches to the target thickness may be determined. If the total thickness does not reach the target thickness, then a super cycle repeating the second step (X times) and the third step (Y times) may be carried out a plurality of times (M times).

Fifth step 109: a post treatment may be carried out after the total thickness of the first layer and the second layer formed through the second step 103 and the third step 105 respectively reaches to the target thickness.

The post treatment may densify a film and improve a film strength. Generally, a non-crystalline film may be crystallized by a post treatment. But in the disclosure, to suppress the crystallization of the first layer, a cycle ratio of the second step 103 for forming the first layer to the third step 105 for forming the second layer may be set at certain ratio. Therefore, the crystallization of the first layer may be suppressed even though the fifth step, a post treatment step is carried out.

The second step, the third step, and the fifth step may be carried out in one reactor in-situ or at least one of the second step, the third step, and the fifth step may be carried out in other reactor ex-situ.

The post treatment may be at least one of thermal annealing, plasma treatment, UV treatment, chemical treatment, or equivalents thereof.

Sixth step 111: After completing the formation of the first layer and the second layer and the post treatment, the substrate processing may be terminated and the substrate may be unloaded.

FIG. 5 is a view of timing graph for processing a substrate according to an embodiment of the disclosure.

A step T1 to a step T4 of FIG. 5 may correspond to the second step 103 of FIG. 4, and a step T5 to a step T8 of FIG. 5 may correspond to the third step 105 of FIG. 4. In an embodiment, the first source gas supplied in the step T1 of FIG. 5 may contain a titanium (Ti) and the second source gas supplied in the step T5 of FIG. 5 may contain a silicon (Si) or a titanium (Ti), the same as the first source gas.

In FIG. 5, the first reactant and the second reactant may react chemically with the first source gas and the second source gas respectively when RF power is applied and a plasma is generated. But the first reactant and the second reactant may not react chemically with the first source gas and the second source gas respectively when RF power is not applied and a plasma is not generated. In that case, the first reactant and the second reactant may act as a reactive purge gas, just purging the first source gas and the second source gas respectively.

The first reactant and the second reactant may be the same gases or different gases. In an embodiment, the first reactant may contain an oxygen and the second reactant may contain an oxygen or a nitrogen.

As shown in FIG. 5, a step T1 to a step T4 for forming a first layer and a step T5 to a step T8 for forming a second layer may be repeated a plurality of times respectively (e.g. X times and Y times), comprising a cycle respectively. A super cycle may be comprised of cycles and be repeated a plurality of times (e.g. M times).

Table 1 illustrates a film phase (crystalline or non-crystalline) of TiO₂—SiO₂ layer in which a TiO₂ layer is a first layer and a SiO₂ layer is a second layer in accordance with the thickness of each layer, a cycle ratio of the step for forming TiO₂ layer as a first layer to the step for forming SiO₂ layer as a second layer as shown in FIG. 4 and FIG. 5 and before/after the post treatment (e.g. thermal annealing). Ain an embodiment according to Table 1, a layer is formed at 190° C. and a thermal annealing is carried out at 400° C. for 170 seconds.

TABLE 1
film properties according to the cycle ratio of TiO₂ layer to
SiO₂ layer, a respective film thickness and a post treatment

| | Cycle | Thickness(Å) | | After annealing |
|---|---|---|---|---|
| Deposition | ratio(X:Y) | (TiO₂ or | Before | (400° C., 170 |
| temperature(° C.) | (TiO₂:SiO₂) | TiO₂ + SiO₂) | annealing | seconds) |
| 190° C. | 5:1 | 400 | Non-crystalline | Non-crystalline |
| | | 700 | Non-crystalline | Non-crystalline |
| | | 1000 | Non-crystalline | Non-crystalline |
| | 10:1 | 400 | Non-crystalline | Non-crystalline |
| | | 700 | Non-crystalline | Non-crystalline |
| | | 1000 | Non-crystalline | Non-crystalline |
| | 20:1 | 400 | Non-crystalline | Non-crystalline |
| | | 700 | Non-crystalline | Crystalline |
| | | 1000 | Non-crystalline | Crystalline |
| | 100:0 | 400 | Non-crystalline | Crystalline |
| | (TiO₂) | 700 | Crystalline | Crystalline |
| | | 1000 | Crystalline | Crystalline |

As illustrated in Table 1, a TiO₂ layer may be non-crystalline when the layer is thin (e.g. 400 Å) before a post treatment (e.g. thermal annealing), but may be crystalline after a post treatment regardless of the thickness.

But as illustrated in Table 1, a film phase of TiO₂—SiO₂ laminated layer after annealing at 400° C. may be determined by the cycle ratio of the step for forming TiO₂ layer to the step for forming SiO₂ layer, X:Y as shown in FIG. 5 and a thickness of TiO₂—SiO₂ laminated layer.

In more detail, as the cycle ratio becomes lower, for instance, X:Y becomes 20:1 to 10:1 to 5:1, and TiO₂—SiO₂ laminated layer becomes thinner, a film phase after a thermal annealing may be non-crystalline. Specifically, when the cycle ratio of X to Y (X:Y) is below 10:1, TiO₂—SiO₂ laminated layer after annealing at 400° C. may be non-crystalline even though a TiO₂—SiO₂ laminated layer is as thick as 1,000 Å.

In an embodiment according to Table 1, the number of cycles for forming a SiO₂ layer in forming a TiO₂—SiO₂ laminated layer may be minimized to maintain the high dielectric constant and the high film strength of TiO₂ layer, but to maintain a non-crystalline TiO₂ layer. Therefore, in TiO₂—SiO₂ laminated layer of 1,000 Å thickness or below, it may be preferable to set the cycle ratio of the step of forming TiO₂ layer to the step of forming SiO₂ layer below 10:1 (≤10:1) (e.g. 10:1, 5:1, or 3:1), increasing the number of cycles for forming a TiO₂ layer to the maximum, but maintaining a non-crystalline TiO₂ layer even after annealing. But the thickness of TiO₂—SiO₂ layer is not limited thereto. In another embodiment, a TiO₂—SiO₂ laminated layer may be 1 um (10,000 Å) or below.

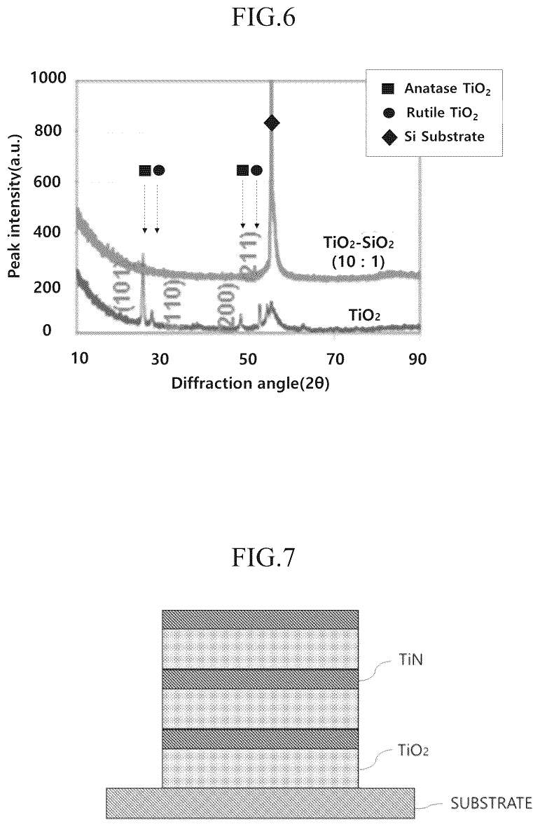

FIG. 6 is an XRD (X-Ray Diffraction) data showing a crystallinity of TiO₂ layer and TiO₂—SiO₂ laminated layer after a thermal annealing in which a cycle ratio of the step of forming a TiO₂ layer to the step of forming a SiO₂ layer is 10:1. In FIG. 6, a TiO₂ layer and a TiO₂—SiO₂ laminated layer are formed at 120° C. and thermally annealed at 800° C. for 30 minutes.

In FIG. 6, a TiO₂ layer after carrying out a thermal annealing may be crystallized containing an anatase crystal phase indicated as (101) and (200) peaks, and a rutile crystal phase indicated as (110) and (211) peaks. It is commonly known that TiO₂ has three crystalline phases, e.g. anatase, rutile and brookite. Of them, the anatase and the rutile phases are more stable than the brookite phase. Therefore FIG. 6 shows that TiO₂ layer may be polycrystalline (e.g. anatase and rutile phases) after annealing according to the test conditions of the disclosure.

But a TiO₂—SiO₂ laminated layer with a cycle ratio of 10 to 1 may maintain a non-crystalline phase even after a thermal annealing. Therefore, the disclosure has a technical benefit that TiO₂—SiO₂ laminated layer with a cycle ratio of 10 to 1 or below (10≤1) for TiO₂ layer to SiO₂ layer may prevent bumps from being generated on the surface of the layer after a thermal annealing.

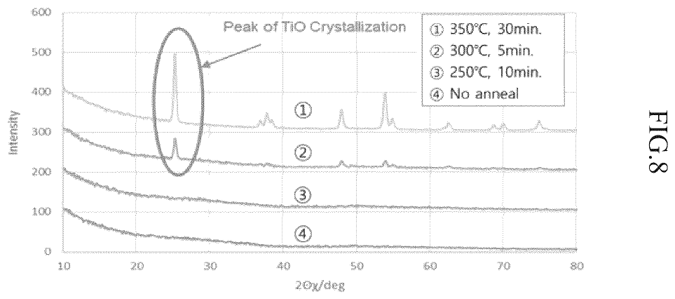

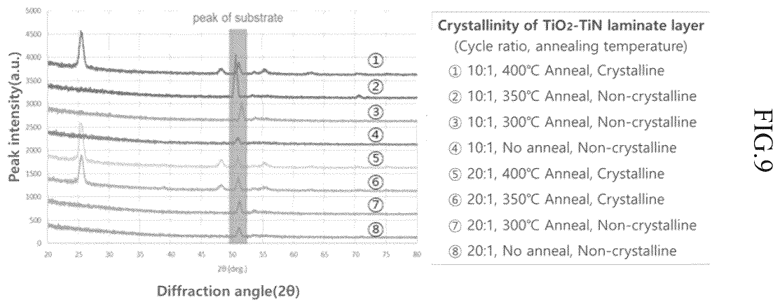

FIG. 7 illustrates another embodiment of the disclosure in which a laminated layer may comprise TiO₂—TiN layer formed on the substrate.

In FIG. 7, a TiO₂—TiN laminated layer may be formed by alternately forming a TiN layer and a TiO₂ layer. A TiO₂ layer may be formed by supplying a titanium-containing source gas and an oxygen-containing reactant alternately and sequentially by plasma atomic layer deposition and the unit cycle may be repeated a plurality of times (e.g. X times). A TiN layer may be formed by supplying a titanium-containing source gas and a nitrogen-containing reactant alternately and sequentially by plasma atomic layer deposition method and the unit cycle may be repeated a plurality of times (e.g. Y times). To suppress the crystallization of TiO₂ layer, a cycle ratio of the step for forming a TiO₂ layer to the step for forming a TiN layer may be set at certain ratio.

FIG. 8 is a XRD (X-Ray Diffraction) data showing a crystallinity of TiO₂ layer in accordance with the annealing temperature. In FIG. 8, a TiO₂ layer may be formed at 190° C. and thermally annealed at 250° C., 300° C. and 350° C. As shown in FIG. 8, a TiO₂ layer is crystallized when annealed at 300° C. and °350° C. as the layer contains an anatase crystal phase peak at around 25 diffraction angle(2θ).

FIG. 9 is a XRD (X-Ray Diffraction) data showing a crystallinity of TiO₂—TiN laminated layer in accordance with the cycle ratio of forming a TiO₂ layer to forming a TiN layer and annealing temperature.

In an embodiment of FIG. 9, a TiO₂—TiN laminated layer may be formed at 190° C. and the cycle ratio of the step for forming a TiO₂ layer to the step for forming a TiN layer may be set at 10:1 and 20:1. The TiO₂—TiN laminated layer may be annealed at 300° C., 350° C. and 400° C.

As shown in FIG. 8, a TiO₂ layer is crystallized when the TiO₂ layer is annealed at 300° C. In contrast, as shown in FIG. 9, a TiO₂—TiN laminated layer with a cycle ratio of 20 to 1 may maintain a non-crystalline phase even when the layer is annealed at 300° C. (\textcircled{7} of FIG. 9).

FIG. 9 also shows that as the number of cycle for forming a TiN layer increases (e.g. lower cycle ratio of TiO₂ to TiN), the TiO₂—TiN laminated layer may maintain a non-crystalline phase even at higher annealing temperature (e.g. \textcircled{2} vs. \textcircled{6} in FIG. 9).

In another embodiment of the disclosure, other layers may be formed on TiO₂ layer. For example, the laminated layer may comprise at least one of TiO₂—SiN, TiO₂—TaN to suppress the crystallization of TiO₂ layer. Therefore the second source gas may contain at least one of silicon, titanium and tantalum.

As shown in Table1, FIG. 8 and FIG. 9, it may be found that conditions for suppressing a crystallization of TiO₂ layer may be determined by the cycle ratio of the step for forming a TiO₂ layer to the step for forming the other layer (e.g. SiO₂, TiN, SiN, TaN, or mixtures thereof, or any oxide, nitride or metal layer etc.), a type of the other layer (e.g. SiO₂, TiN, SiN, TaN, or mixtures thereof, or any oxide, nitride or metal layer etc.), a thickness of laminated layer and annealing temperature.

Therefore, according to embodiments of the disclosure, the disclosure may have a technical benefit that the crystallization temperature of TiO₂ layer may be controlled by adding a different layer (e.g. SiO₂, TiN, SiN, TaN, or mixtures thereof, or any oxide, nitride or metal layer) and forming a laminated layer with a cycle ratio of the step for forming a TiO₂ layer to the step for forming another layer being 20:1 or below.

As shown in FIG. 8 to FIG. 9, the first source gas for forming a first layer may contain a titanium and the second source gas for forming a second layer may contain a titanium. In an embodiment, the first source gas and the second source gas may be the same. For instance, the first source gas and the second source gas may be at least one of Tetrikis-Dimethylamino Titanium(TDMAT), Ti[N(CH₃)₂]₄; Tetra-ethylmethylamino Titanium(TEMATi), [(CH₃C₂H₅)N]₄Ti); Titanium alkoxide(e.g. Titanium tetraisopropoxide (TTIP), Ti(OC₃H₇)₄; Titanium tetrabutoxide, Ti[OC(CH₃)₃]₄); Titanium tetrachloride, TiCl₄; or mixtures thereof.

Table 2 is experimental conditions for TiO₂—SiO₂ laminated layer.

TABLE 2
a test condition for TiO₂—SiO₂ laminated layer

| Process parameter | | Detailed condition |
|---|---|---|
| Process time | Source feeding | 0.2 to 1.2 (preferably 0.4 to 1.0) |
| per step | Source purge | 0.2 to 1.2 (preferably 0.4 to 1.0) |
| (second) | Plasma-on | 0.2 to 1.2 (preferably 0.4 to 1.0) |
| (TiO₂, SiO₂) | Purge | 0.2 to 1.2 (preferably 0.4 to 1.0) |
| Gas flow rate | Source carrier Ar | 500 to 1,500 (preferably 700 to 1,200) |
| (sccm) | Purge Ar | 2,000 to 10,000 (preferably 4,000 to 8,000) |
| (TiO₂, SiO₂) | Reactant | 50 to 500 (preferably 100 to 400) |
| Plasma | RF power (W) | 50 to 600 (preferably 100 to 500) |
| condition | RF frequency | 10 to 60 |
| | (MHz) | |

| | |
|---|---|
| Deposition temperature(° C.) | 100 to 200 |
| Annealing condition | 300° C. to 850° C., 30 seconds to 30 minutes |
| Si source | Silicon-containing gas |
| Ti source | Titanium-containing gas |
| Reactant | Oxygen-containing gas |

A first source gas may contain a titanium and a second source gas may contain at least one of silicon, titanium, tantalum and the mixture thereof. In an embodiment, the first source gas containing a titanium and the second source gas containing a titanium may be the same.

A titanium-containing gas may be at least one of: Tetrikis-Dimethylamino Titanium(TDMAT), Ti[N(CH₃)₂]₄;Tetra-ethylmethylamino Titanium(TEMATi), [(CH₃C₂H₅)N]₄Ti); Titanium alkoxide(e.g. Titanium tetra isopropoxide(TTIP), Ti(OC₃H₇)₄; Titanium tetrabutoxide, Ti[OC(CH₃)₃]₄); Titanium tetrachloride, TiCl₄ or mixtures thereof.

A silicon-containing gas may be at least one of: TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; or mixtures thereof.

A tantalum-containing gas may be at last one of: Tertiary-Butyl Imido Tris-Diethyl Tantalum (TBTDET), [(^{t}BuN)Ta(N(C₂H₅)₂)₃]; Tertiary-Butyl Imido Tris-Ethylmethylamino Tantalum (TBITEMATa), [(^{t}BuN)Ta(N(CH₃)(C₂H₅))₃]; or mixtures thereof.

A first reactant may contain an oxygen and a second reactant may contain at least one of oxygen, nitrogen and the mixture thereof. In one embodiment, an oxygen-containing gas may be at least one of: O₂, CO₂, O₃, N₂O, NO₂, or mixtures thereof, and a nitrogen-containing gas may be at least one of: N₂, NH₃, N₂H₂, N₂H₄, or mixtures thereof.

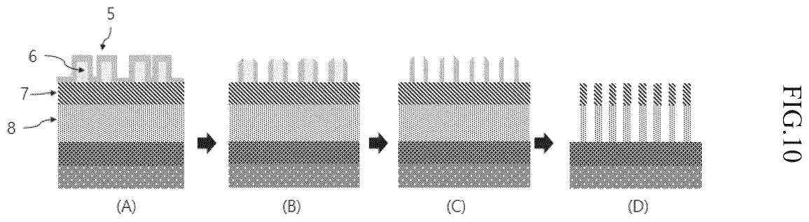

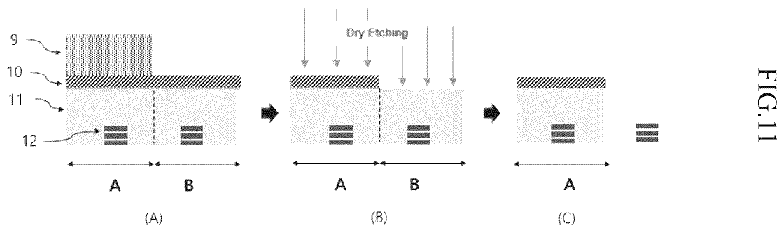

FIG. 10(A) to FIG. 10(C) illustrate an application of TiO₂—SiO₂ laminated layer as a spacer layer formed on a substrate in patterning process according to the disclosure.

In FIG. 10(A), a hard mask oxide layer 7 may be formed on the poly silicon layer 8 and a TiO₂—SiO₂ laminated layer 5 may be formed the patterned carbon layer 6 which may be formed on the hard mask oxide layer 7. In the next step FIG. 10(B), an anisotropic etching step, an upper portion of TiO₂—SiO₂ layer may be removed. In FIG. 10(C), a selective etching step, a carbon layer 6 may be removed and a TiO₂—SiO₂ laminated layer may remain as a spacer layer for hard mask patterning. In FIG. 10(D), a TiO₂—SiO₂ mask layer may be removed and the hard mask layer 7 may be patterned conformally.

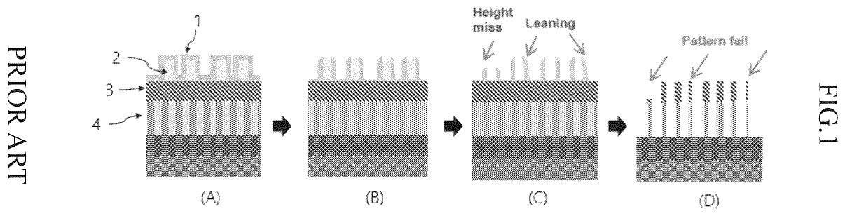

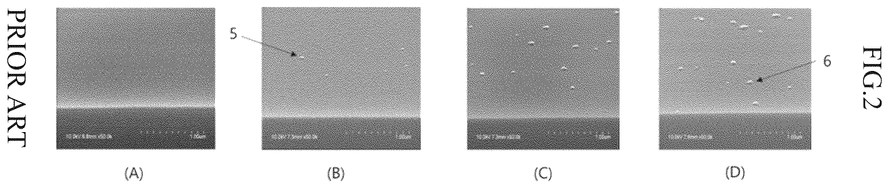

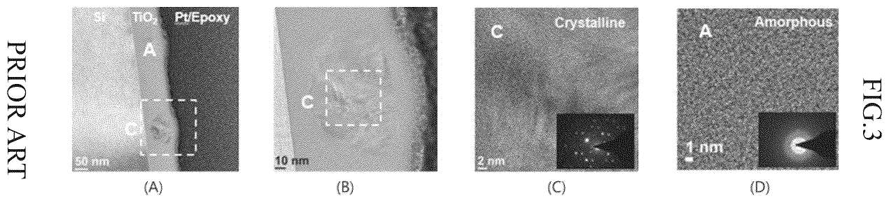

As shown in FIG. 10(C), a TiO₂—SiO₂ spacer layer may have high strength and may not lean or be over etched compared to the conventional SiO₂ spacer layer as shown in FIG. 1(C). Therefore, the disclosure may have a technical benefit that defects (e.g. non-uniform spacing between spacer layers) may not occur during patterning a poly silicon layer 8. The disclosure may also have an additional technical benefit that TiO₂—SiO₂ spacer layer may be non-crystalline and may not contain a crystal phase, therefore a wet etch rate deviation between spacer layers may not occur.

FIG. 11(A) to FIG. 11(C) illustrate another application of TiO₂—SiO₂ laminated layer as a hard mask layer formed on the substrate in patterning process.

In FIG. 11(A), a TiO₂—SiO₂ hard mask layer 10 may be formed on the BARC (Bottom Anti-Reflective Coating) layer 11 formed on the semiconductor device structure 12 and a photo resist layer 9 may be formed on the hard mask layer 10. The photo resist layer 9 may be formed in area ‘A’ of the BARC layer 11 and may not be formed in area ‘B’ which may be etched out later.

In FIG. 11(B), a photo resist layer 9 in area ‘A’ and a TiO₂—SiO₂ hard mask layer 10 in area ‘B’ may be removed first by a first dry etching. After that, the BARC layer 11 in area ‘B’ may be removed afterwards by a second dry etching (FIG. 11(C)). A TiO₂—SiO₂ hard mask layer 10 remained in area ‘A’ may have high strength compared to the conventional SiO₂ hard mask layer and may not be etched out during an etching step to remove the photo resist layer 9. Therefore the disclosure may have a technical benefit that a TiO₂—SiO₂ laminated layer may act as a mask layer and facilitate a selective etching.

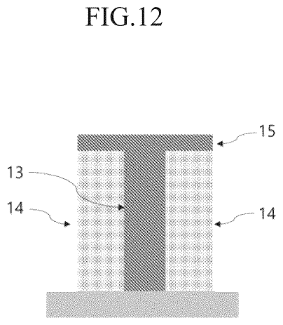

FIG. 12 illustrates another application of TiO₂—SiO₂ laminated layer for barrier layer in interconnection process.

In FIG. 12, a gap formed between metal lines 14 may be filled with TiO₂—SiO₂ insulating layer for the insulation between metal lines 14.

As the degree of integration of semiconductor device increases, the size and the width of gap decrease. Therefore when the gap is filled with the conventional SiO₂ insulating layer, a dielectric breakdown may occur due to thin thickness of SiO₂ layer, leading to a decline of electric characteristics of the device. In contrast, when the gap is filled with TiO₂—SiO₂ laminated layer, due to TiO₂ layer with high dielectric constant and SiO₂ layer suppressing the crystallization of TiO₂ layer, a non-crystalline TiO₂—SiO₂ laminated layer with high insulating characteristics may be maintained. Therefore, the disclosure may have a technical benefit that a TiO₂—SiO₂ laminated layer filling a gap may prevent the dielectric breakdown in narrow gap structure.

A TiO₂—SiO₂ laminated layer may also be applied to an optical layer of CIS (CMOS Image Sensor) device. A TiO₂ layer may be crystalline and increase a surface roughness of the TiO₂ layer. Therefore, a crystalline TiO₂ layer may cause a light scattering and the optical characteristics of the CIS device may deteriorate. In contrast, a TiO₂—SiO₂ laminated layer according to the disclosure may be non-crystalline, therefore a TiO₂—SiO₂ laminated layer may improve optical characteristics of the CIS device.

A thickness of TiO₂—SiO₂ layer may vary depending on its application. In hard mask application, the thickness of the laminated layer may be 20 nm or so, and in dielectric layer application for optical layer of CIS (CMOS Image Sensor) device, the thickness of the laminated layer may range from 500 nm to 1 um.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing method comprising:
a step for loading a substrate onto a reactor;
a step for forming a first layer on the substrate;
a step for forming a second layer on the first layer, wherein a combination of the first layer and the second layer forms a laminated layer; and
a step for post treatment to the laminated layer.

2. The method of claim 1, wherein the step for forming the first layer and the step for forming the second layer are cyclically repeated a plurality of times respectively.

3. The method of claim 1, wherein the step for forming the first layer and the step for forming the second layer comprise a super cycle and the super cycle is repeated a plurality of times.

4. The method of claim 2, wherein the step for forming the first layer comprising:
a step for supplying a first source gas;
a step for supplying a first reactant; and
a step for applying RF power and activating the first reactant, wherein the step for forming the first layer is repeated a plurality of times.

5. The method of claim 2, wherein the cycle of the step for forming the second layer comprising:
a step for supplying a second source gas;
a step for supplying a second reactant; and
a step for applying RF power and activating the second reactant, wherein the step for forming the second layer is repeated a plurality of times.

6. The method of claim 2, wherein a cycle ratio of the step for forming the first layer to the step for forming the second layer is 20:1 or below.

7. The method of claim 6, wherein a cycle ratio of the step for forming the first layer to the step for forming the second layer is 10:1 or below.

8. The method of claim 2, wherein the thickness of the laminated layer comprising the first layer and the second layer is 10,000 Å or below.

9. The method of claim 8, wherein the thickness of the laminated layer comprising the first layer and the second layer is 1,000 Å or below.

10. The method of claim 1, wherein the laminated layer is non-crystalline.

11. The method of claim 4, wherein the first source gas is at least one of: Tetrikis-Dimethylamino Titanium(TDMAT), Ti[N(CH₃)₂]₄; Tetra-ethylmethylamino Titanium(TEMATi), [(CH₃C₂H₅)N]4Ti); Titanium alkoxide; Titanium tetrachloride, TiCl₄; or mixtures thereof.

12. The method of claim 5, wherein the second source gas is at least one of: TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; Tetrikis-Dimethylamino Titanium(TDMAT), Ti[N(CH₃)₂]₄; Tetra-ethylmethylamino Titanium(TEMATi), [(CH₃C₂H₅)N]₄Ti); Titanium alkoxide; Titanium tetrachloride, TiCl₄; Tertiary-Butyl Imido Tris-Diethyl Tantalum (TBTDET), [(^{t}BuN)Ta(N(C₂H₅)₂)₃]; Tertiary-Butyl Imido Tris-Ethylmethylamino Tantalum (TBITEMATa), [(^{t}BuN)Ta(N(CH₃)(C₂H₅))₃]; or mixtures thereof.

13. The method of claim 4, wherein the first reactant is at least one of: O₂, CO₂, O₃, N₂O, NO₂, or mixtures thereof.

14. The method of claim 5, wherein the second reactant is at last one of: O₂, CO₂, O₃, N₂O, NO₂, N₂, NH₃, N₂H₂, N₂H₄; or mixtures thereof.

15. The method of claim 1, wherein the first layer comprises TiO₂ and the second layer comprises at least one of: SiO₂, SiN, TiN, TaN, or mixtures thereof.

16. The method of claim 1, wherein the post treatment is at least one of annealing, plasma treatment, UV treatment, or chemical treatment; and wherein a strength of the laminated layer increases by the post treatment.

17. The method of claim 16, wherein the thermal annealing is carried out at 850° C. or below.

18. The method of claim 17, wherein the thermal annealing is carried out at 400° C. or below.

19. The method of claim 1, wherein the laminated layer comprising the first layer and the second layer is at least one of spacer layer, hard mask layer, gap-filling layer, or optical layer.
